(19) United States
(12) Patent Application Publication
(10) Pub. No.: US 2014/0027763 A1
(43) Pub. Date: Jan. 30, 2014

(54) THIN FILM TRANSISTOR SUBSTRATE AND DISPLAY DEVICE HAVING THE THIN FILM TRANSISTOR SUBSTRATE

(71) Applicant: InnoLux Corporation, Miao-Li County (TW)

(72) Inventors: Hung-Ming SHEN, Miao-Li County (TW); Wan-Ling HUANG, Miao-Li County (TW); Kai-Neng YANG, Miao-Li County (TW); Tsau-Hua HSIEH, Miao-Li County (TW)

(73) Assignee: InnoLux Corporation, Miao-Li County (TW)

(21) Appl. No.: 13/945,450

(22) Filed: Jul. 18, 2013

(30) Foreign Application Priority Data
Jul. 25, 2012 (TW) 101126829

(51) Int. Cl. H01L 29/786

(52) U.S. Cl. CPC H01L 29/7869
USPC 257/43

(57) ABSTRACT

A thin film transistor substrate includes a substrate, a gate, a gate insulating layer, a semiconductor layer, a source, a drain and a light-blocking layer. The gate is disposed on the substrate. The gate insulating layer is disposed on the gate. The semiconductor layer is disposed on the gate insulating layer. The source and the drain are disposed on the semiconductor layer with an interval therebetween. The light-blocking layer is disposed on the interval. The semiconductor layer includes an oxide semiconductor. In addition, a display device is also disclosed.

### CROSS REFERENCE TO RELATED APPLICATIONS

This Non-provisional application claims priority under 35 U.S.C. §119(a) on Patent Application No(s). 101126829 filed in Taiwan, Republic of China on Jul. 25, 2012, the entire contents of which are hereby incorporated by reference.

### BACKGROUND OF THE INVENTION

1. Field of Invention

The invention relates to a thin film transistor substrate and a display device having the thin film transistor substrate.

2. Related Art

With the advance of technology, display devices have been widely applied to all kinds of fields. Especially, optical element display devices, having advantages such as compact structure, low power consumption, light weight and less radiation, gradually take the place of cathode ray tube (CRT) display devices, and are widely applied to various electronic products, such as mobile phones, portable multimedia devices, notebooks, LCD TVs and LCD screens.

With regard to an LCD device, a polysilicon thin film transistor (TFT) thereof is capable of higher mobility of about 100 cm²/Vs. However, the polysilicon TFT needs to be produced at the temperature above 450° C., so it can only be formed on a highly heat-resistant substrate, and is therefore not suitable for the application of a large-size or flexible substrate. As to an amorphous silicon TFT, it can be produced at a lower temperature of about 300° C. However, the amorphous silicon TFT just has mobility of about 1 cm²/Vs, so it can not be applied to the substrate with higher fineness.

Accordingly, it has been proposed to use a metal oxide semiconductor, such as amorphous indium gallium zinc oxide (a-IGZO), as a semiconductor layer of a TFT. Although a-IGZO TFT has better mobility than amorphous silicon TFT, and also can be produced with a simpler process than amorphous silicon TFT, it is very sensitive to light, water and oxygen.

Therefore, it is an important subject to provide a thin film transistor substrate and a display device having the same that can effectively block the light' illumination for increasing the stability of the TFT and also have raised aperture ratio.

### SUMMARY OF THE INVENTION

In view of the foregoing subject, an objective of the invention is to provide a thin film transistor substrate and a display device having the same that can effectively block the light' illumination for increasing the stability of the TFT and also have raised aperture ratio.

To achieve the above objective, a thin film transistor substrate according to the invention comprises a substrate, a gate, a gate insulating layer, a semiconductor layer, a source, a drain, and a light-blocking layer. The gate is disposed on the substrate. The gate insulating layer is disposed on the gate and the substrate. The semiconductor layer is disposed on the gate insulating layer. The source and the drain are disposed on the semiconductor layer with an interval therebetween and contact the semiconductor layer. The light-blocking layer is disposed on the interval. The semiconductor layer includes an oxide semiconductor.

To achieve the above objective, a display device according to the invention comprises a thin film transistor substrate, an opposite substrate, an optical element layer and a backlight module. The thin film transistor substrate includes a substrate, a gate, a gate insulating layer, a semiconductor layer, a source, a drain and a light-blocking layer. The gate is disposed on the substrate, the gate insulating layer is disposed on the gate and the substrate, the semiconductor layer is disposed on the gate insulating layer, the source and the drain are disposed on the semiconductor layer with an interval therebetween, the light-blocking layer disposed on the interval between the source and the drain, and the material of the semiconductor layer includes an oxide semiconductor. The opposite substrate is disposed opposite to the thin film transistor substrate. The optical element layer is disposed between the thin film transistor substrate and the opposite substrate. The backlight module is on the side adjacent to the thin film transistor substrate and faces away from the opposite substrate.

As mentioned above, in the thin film transistor substrate and the display device having the TFT substrate according to the invention, a light-blocking layer is disposed over the interval between the source and the drain to cover the interval, thereby blocking the ways of the light towards the semiconductor layer so as to prevent the semiconductor layer from being illuminated. Therefore, the thin film transistor of the invention can be improved in electric stability, and the aperture ratio also can be increased.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic cross-section of a thin film transistor substrate according to a preferred embodiment of the invention;

FIG. 1B is a schematic cross-section of another thin film transistor substrate according to a preferred embodiment of the invention;

FIGS. 2A to 2C are schematic diagrams of some illustrative varieties of the thin film transistor substrate according to a preferred embodiment of the invention;

FIG. 3 is a schematic cross-section of a display device according to a preferred embodiment of the invention; and

FIGS. 4A to 4C are schematic diagrams of some illustrative varieties of the display device according to a preferred embodiment of the invention.

### DETAILED DESCRIPTION OF THE INVENTION

The present invention will be apparent from the following detailed description, which proceeds with reference to the accompanying drawings, wherein the same references relate to the same elements.

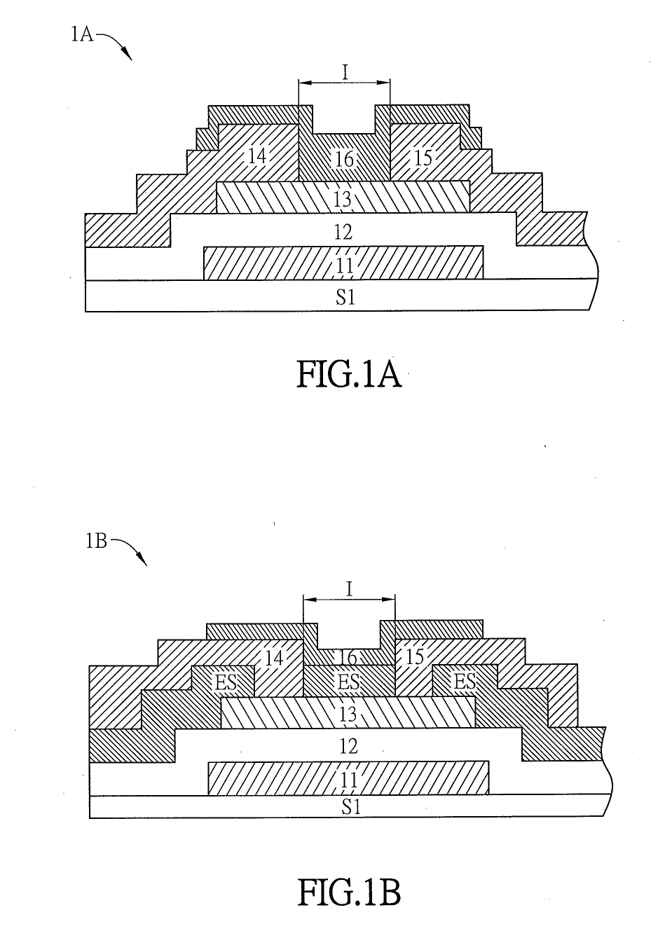

FIG. 1A is a schematic diagram of a thin film transistor (TFT) substrate 1A according to a preferred embodiment of the invention. In FIG. 1A, the TFT substrate 1A includes a substrate S1, a gate 11, a gate insulating layer 12, a semiconductor layer 13, a source 14, a drain 15, and a light-blocking layer 16. In this embodiment, the substrate S1 can be made of a transparent material thus to be applied to a transparent display device. The transparent material is, for example, glass, quartz or the like, plastics, rubber, glass fiber or other polymer material. The substrate S1 is an alumino silicate glass substrate preferably. Otherwise, the substrate S1 can be made of an opaque material thus to be applied to a self-illuminating or reflective display device. In this case, the substrate S1 is, for example, a metal-fiberglass composite plate or a metal-ceramic composite plate.

The gate 11 is disposed on the substrate S1, and can be a single-layer or multi-layer structure made of metal (e.g. aluminum, copper, silver, molybdenum, titanium) or alloy. The conductive wire, such as the scan line, for transmitting driving signals can be made at the same process and layer as the gate 11, and is connected to the gate 11. The gate insulating layer 12 is disposed on the gate 11, and can be made of organic material such as organic silicone compound, or inorganic material such as silicon nitride, silicon oxide, silicon oxynitride, silicon carbide, aluminum oxide or hafnium oxide. The gate insulating layer 12 also can be a multi-layer structure including any combination of the aforementioned materials. The gate insulating layer 12 fully covers the gate 11 for the insulation from the other electrodes, and can partially or fully cover the substrate S1.

The semiconductor layer 13 is disposed on the gate insulating layer 12 and opposite to the gate 11. In this embodiment, the material of the semiconductor layer 13 includes an oxide semiconductor containing an oxide including at least one of indium, zinc and tin. The oxide semiconductor is amorphous indium gallium zinc oxide (a-IGZO) preferably.

The source 14 and the drain 15 are disposed on the semiconductor layer 13, and contact the semiconductor layer 13. The source 14 and the drain 15 are on the opposite sides corresponding to the gate 11 with an interval I therebetween. When the semiconductor layer of the thin film transistor is not conducted, the source 14 and the drain 15 are separated electrically. The materials of the source 14 and the drain 15 can be metal (e.g. aluminum, copper, silver, molybdenum, titanium) or alloy, and the source 14 or the drain 15 can be a single-layer or multi-layer structure. The conductive wire, such as the data line, for transmitting driving signals can be made at the same process and layer as the source 14 and the drain 15.

The light-blocking layer 16 is disposed on the interval I, and covers the interval I. The material of the light-blocking layer 16 includes chromium, acrylic resin, or TiO₂. When the material of the light-blocking layer 16 includes acrylic resin, it further includes carbon or black dye.

In this embodiment, the thickness of the light-blocking layer 16 is preferably between 0.15 μm and 1.2 μm, and the optical density (OD, or absorbance) of that is preferably between 4 and 6. Moreover, for preventing the light from illuminating the semiconductor layer 13 and blocking the ways of the light towards the semiconductor layer 13, the light-blocking layer 16 along a projection direction exceeds the edge of the semiconductor layer 312 by at least 1 μm and preferably by an amount between 1 μm and 2 μm. Besides, because of the material and manufacturing process of the light-blocking layer 16, an outer edge of the light-blocking layer 16 is an oblique surface extending towards the surface of the substrate S1. In other words, the outer edge of the light-blocking layer 16 has an inclined angle which is between 25° and 60° on the horizontal direction.

In this embodiment, the source 14 and the drain 15 are directly disposed on the semiconductor layer 13 and contact the semiconductor layer 13. However, the invention is not limited thereto. For example in FIG. 1B, by other manufacturing process, the source 14 and the drain 15 of the TFT substrate 1B are disposed on an etch stop layer ES, and respectively contact the semiconductor layer 13 through the openings of the etch stop layer ES. The etch stop layer ES can include inorganic material, such as silicon nitride, silicon oxide, silicon oxynitride, silicon carbide, aluminum oxide or hafnium oxide, and can be a single-layer or multi-layer structure.

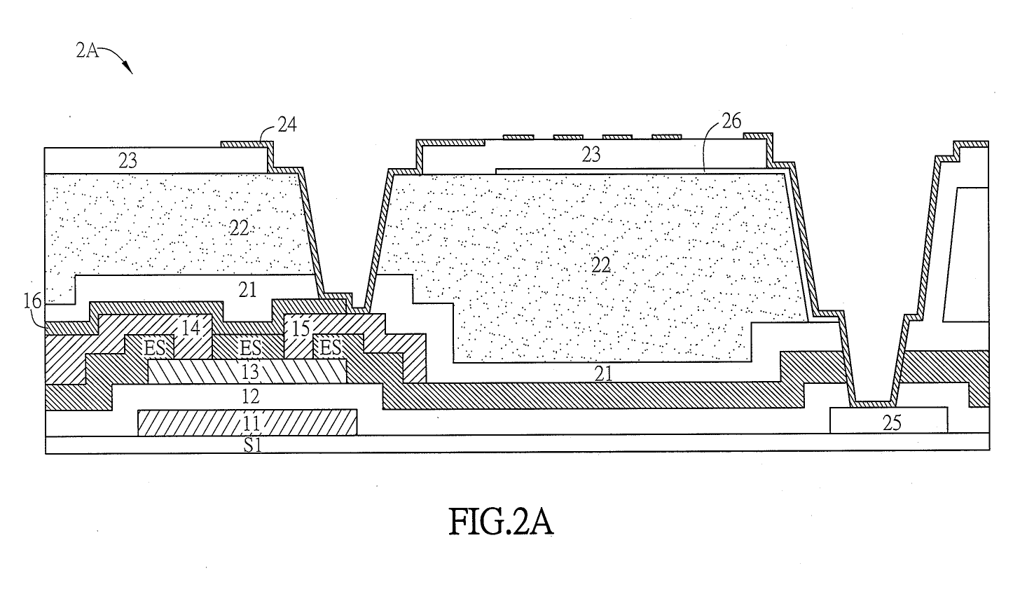

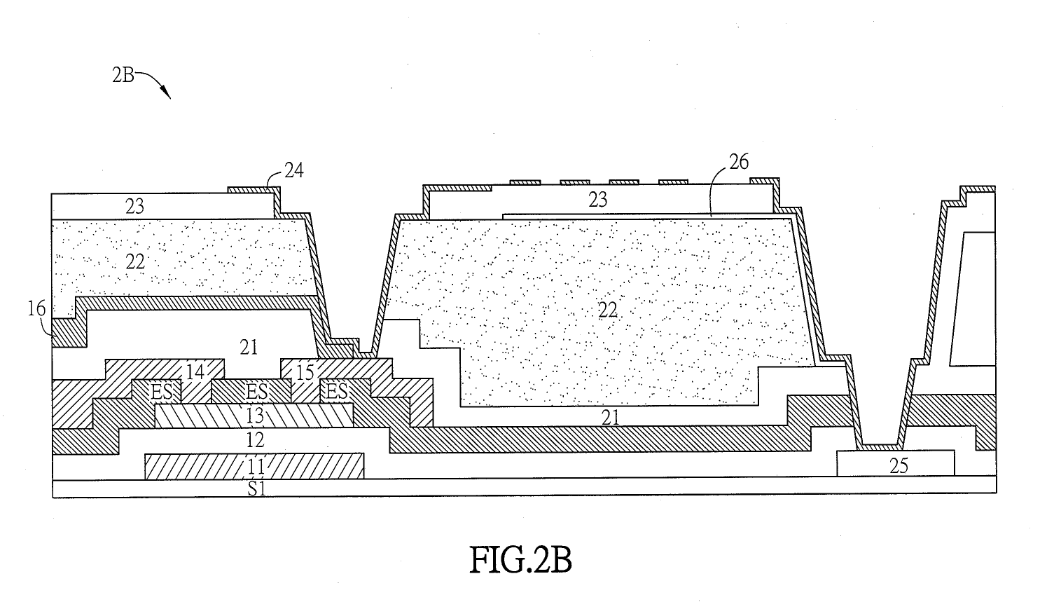

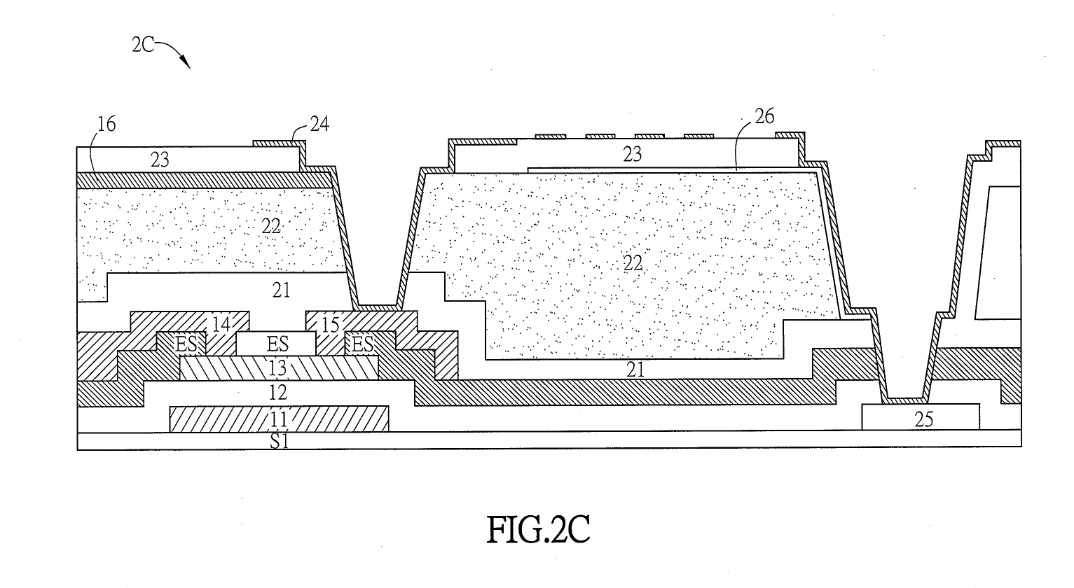

FIGS. 2A to 2C are schematic diagrams of some illustrative varieties of the thin film transistor substrate according to a preferred embodiment of the invention. In FIG. 2A, different from the TFT substrate 1B, the TFT substrate 2A further includes a first passivation layer 21, a light-absorbing layer 22, a second passivation layer 23, and a transparent conductive layer 24.

In this embodiment, the first passivation layer 21 is disposed on the light-blocking layer 16. The light-absorbing layer 22 is disposed on the first passivation layer 21, and the thickness thereof is between 1 μm and 2.5 μm. The second passivation layer 23 is disposed on the light-absorbing layer 22. The transparent conductive layer 24 is disposed on the second passivation layer 23, and the material thereof can be ITO, IZO, AZO, CTO, SnO2, ZnO, or other transparent conductive material. The light-absorbing layer 22 includes, for example, organic dielectric material, and can absorb the light of the wavelength under 400 nanometers. Especially, the light-absorbing layer 22 can absorb the light from a backlight module (not shown) reflected towards the light-blocking layer 16 to further block the light from illuminating the semiconductor layer 13 so as to avoid the electric degradation of the semiconductor layer 13. The light-absorbing layer 22 can be made of color filter material.

In FIG. 2B, in comparison with the TFT substrate 2A, the TFT substrate 2B has the first passivation layer 21 disposed on the source 14 and the drain 15. The light-absorbing layer 22 is disposed on the light-blocking layer 16. The second passivation layer 23 is disposed on the light-absorbing layer 22. The transparent conductive layer 24 is disposed on the second passivation layer 23. In FIG. 2C, the first passivation layer 23 of the TFT substrate 2C is disposed on the source 14 and the drain 15. The light-absorbing layer 22 is disposed on the first passivation layer 21. The second passivation layer 23 is disposed on the light-blocking layer 16. The transparent conductive layer 24 is disposed on the second passivation layer 23.

To be noted, for the convenient illustration, the relation between the thickness and the width of each element shown in FIGS. 1A and 1B and FIGS. 2A to 2C is just for example, but not for representing the actual size. Besides, as an embodiment, the TFT substrate can further include a common electrode and a conductive layer. As shown in FIGS. 2A to 2C, the common electrode 25 is disposed on the substrate 51, and the conductive layer 26 is disposed between the second passivation layer 23 and the light-absorbing layer 22, extends towards the common electrode 25 along the light-absorbing layer 22, and is electrically connected to the common electrode 25. Because the common electrode 25 and the conductive layer 26 with their materials and dispositions are well know by those skilled in the art, they are not described here for concise purpose.

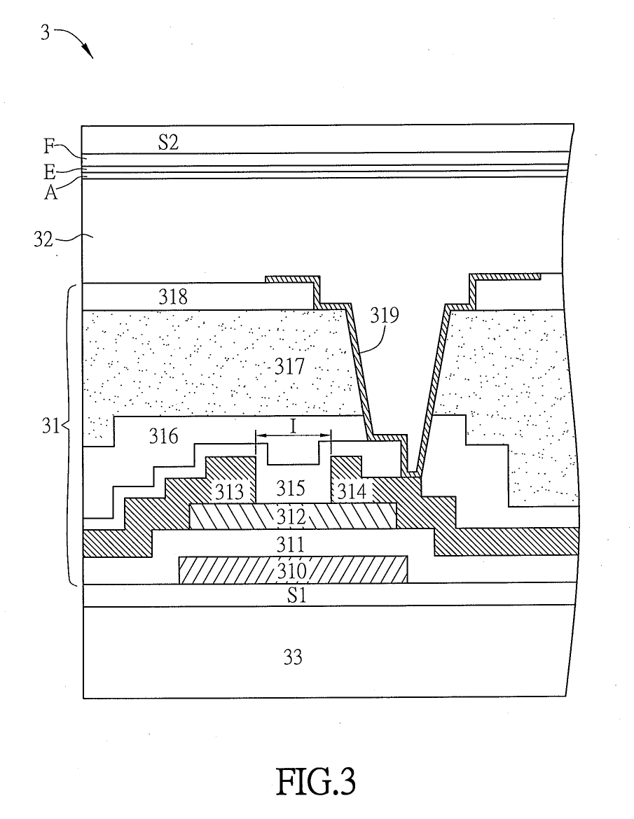

FIG. 3 is a schematic diagram of a display device 3 according to a preferred embodiment of the invention. In FIG. 3, the display device 3 includes a TFT substrate 31, an opposite substrate S2, an optical element layer 32 (e.g. liquid crystal, organic light emission diode, Electrophoretic particle), and a backlight module 33 (just for that the optical element is liquid crystal).

The TFT substrate 31 includes a substrate S1, a gate 310, a gate insulating layer 311, a semiconductor layer 312, a source 313, a drain electrode 314, a light-blocking layer 315, a first passivation layer 316, a light-absorbing layer 317, a second passivation layer 318, and a transparent conductive layer 319. The gate 310 is disposed on the substrate S1. The substrate S1 can be made of transparent material, such as glass, quartz, or the like.

The gate insulating layer 311 is disposed on the gate 310. The semiconductor layer 312 is disposed on the gate insulating layer 311, and includes an oxide semiconductor, which has an oxide including at least one of indium, zinc and tin. The oxide semiconductor is amorphous indium gallium zinc oxide (a-IGZO) preferably.

The source 313 and the drain 314 are disposed on the semiconductor layer 312 with an interval I therebetween, and contact the semiconductor layer 312. The material of the gate 310, the source 313 and the drain 314 can be metal or alloy, and the gate 310, the source 313 and the drain 314 each can be a single-layer or multi-layer structure. The light-blocking layer 315 is disposed on the interval I, and covers the interval I. The material of the light-blocking layer 315 includes chromium, acrylic resin, or TiO₂. When the material of the light-blocking layer 315 includes acrylic resin, it further includes carbon or black dye.

As an embodiment, the thickness of the light-blocking layer 315 is preferably between 0.15 μm and 1.2 μm, and the optical density of that is preferably between 4 and 6. Moreover, for preventing the light from illuminating the semiconductor layer 312 and blocking the ways of the light towards the semiconductor layer 312, the light-blocking layer 315 along a projection direction exceeds the edge of the semiconductor layer 312 by at least 1 μm and preferably by an amount between 1 μm and 2 μm.

In this embodiment, the first passivation layer 316 is disposed on the light-blocking layer 315. The light-absorbing layer 317 is disposed on the first passivation layer 316, and the thickness thereof is between 1 μm and 2.5 μm. The second passivation layer 318 is disposed on the light-absorbing layer 317. The transparent conductive layer 319 is disposed on the second passivation layer 318, and the material thereof can be ITO, IZO, AZO, CTO, SnO₂, ZnO, or other transparent conductive material. The light-absorbing layer 317 can absorb the light of the wavelength under 400 nanometers. The light-absorbing layer 317 can be made of color filter material.

The opposite substrate S2 is disposed opposite to the TFT substrate 31, and has an electrode layer E and a photo-alignment film A. The opposite substrate S2 can be made of transparent material, such as glass, quartz, or the like. As an embodiment, the substrate S1 of the TFT substrate 31 and the opposite substrate S2 can be made of different material. For example, the opposite substrate S2 is a potash glass substrate while the substrate S1 is an alumino silicate glass substrate. The electrode layer E is disposed on a side of the opposite substrate S2 facing the TFT substrate 31, and the photo-alignment film A is disposed to the electrode layer E. A color filter sheet F can be disposed between the opposite substrate S2 and the electrode layer E for a colorful display.

The optical element layer 32 is disposed between the TFT substrate 31 and the opposite substrate S2. The backlight module 33 is on the side adjacent to the TFT substrate 31 and faces away from the opposite substrate S2, and emits light to allow the light through the substrate S1 and the optical element layer 32 and then out of the opposite substrate S2. Besides, the light-absorbing layer 317 can absorb the light which is emitted by the backlight module 33 and then reflected towards the light-blocking layer 315 to further block the light from illuminating the semiconductor layer 312 so as to avoid the electric degradation of the semiconductor layer 312.

To be noted, by other manufacturing processes, the TFT substrate of the display device can further include an etch stop layer, and the source and the drain of the TFT substrate can be disposed on the etch stop layer and respectively contact the semiconductor layer through the openings of the etch stop layer.

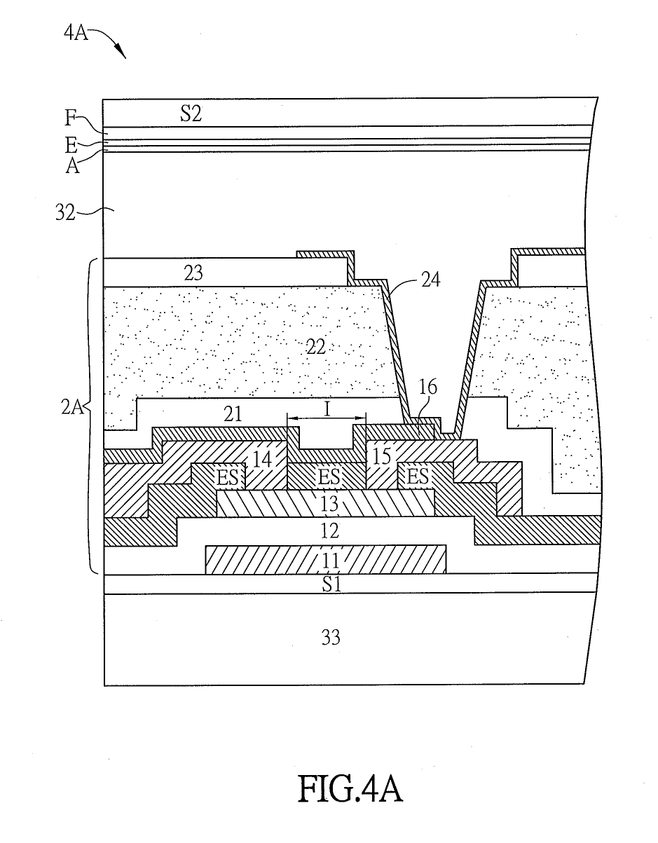

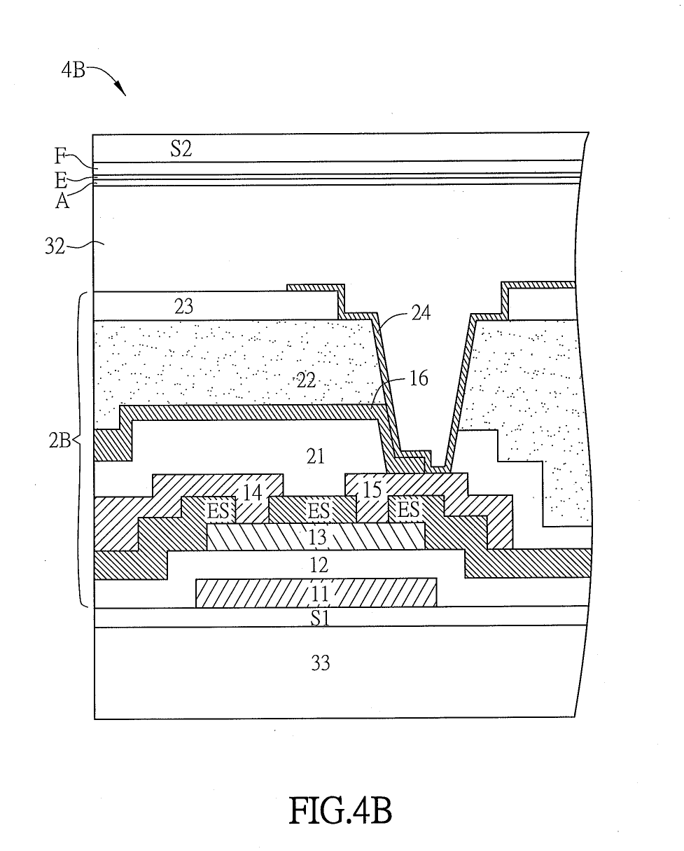

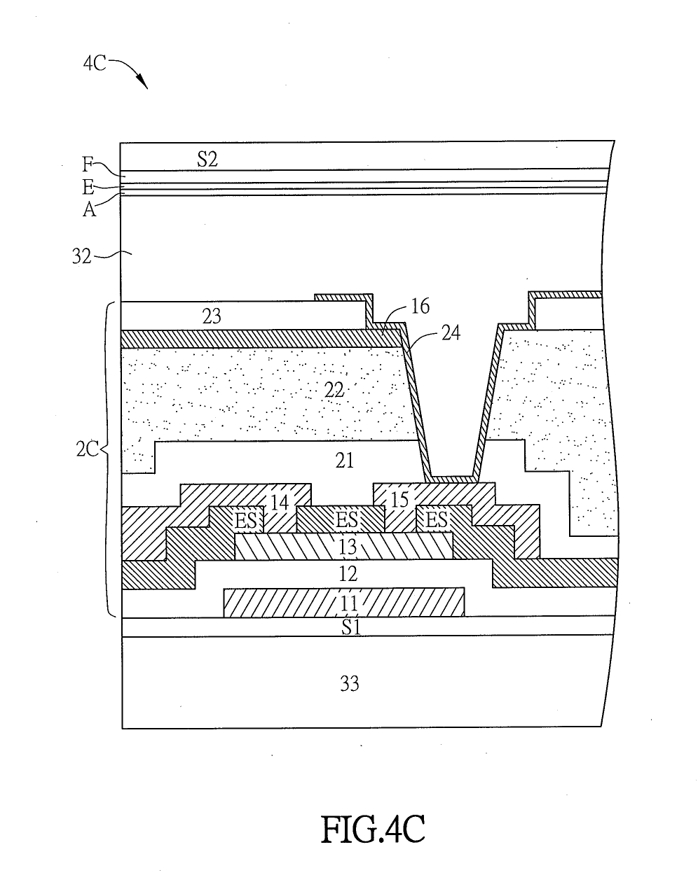

FIGS. 4A to 4C are schematic diagrams of some illustrative varieties of the display device according to a preferred embodiment of the invention. In comparison with the display device 3, the display device 4A in FIG. 4A uses the structure of the TFT substrate 2A. In this embodiment, the source 14 and the drain 15 of the TFT substrate 2A are disposed on the etch stop layer ES. The first passivation layer 21 of the TFT substrate 2A is disposed on the light-blocking layer 16. The light-absorbing layer 22 is disposed on the first passivation layer 21, and the thickness thereof is between 1 μm and 2.5 μm. The second passivation layer 23 is disposed on the light-absorbing layer 22. The transparent conductive layer 24 is disposed on the second passivation layer 23. The light-absorbing layer 22 can absorb the light of the wavelength under 400 nanometers. Especially, the light-absorbing layer 22 can absorb the light from the backlight module 33 reflected towards the light-blocking layer 16 to further block the light from illuminating the semiconductor layer 13. The light-absorbing layer 22 can be made of color filter material.

In comparison with the display device 4A, the display devices 4B and 4C in FIGS. 4B and 4C have the structures of the TFT substrates 2B and 2C, respectively. Because the technical features of the display devices 4B and 4C can be known by referring to the embodiments of the display device 4A and the TFT substrates 2B and 2C, they are not described here for concise purpose.

In summary, in the thin film transistor substrate and the display device having the TFT substrate according to the invention, a light-blocking layer is disposed over the interval between the source and the drain to cover the interval, thereby blocking the ways of the light towards the semiconductor layer so as to prevent the semiconductor layer from being illuminated. Therefore, the thin film transistor of the invention can be improved in electric stability, and the aperture ratio also can be increased.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A thin film transistor substrate, comprising:
a substrate;
a gate disposed on the substrate;
a gate insulating layer disposed on the gate;
a semiconductor layer disposed on the gate insulating layer;
a source and a drain disposed on the semiconductor layer with an interval therebetween; and
a light-blocking layer disposed on the interval, wherein the semiconductor layer includes an oxide semiconductor.

2. The thin film transistor substrate as recited in claim 1, wherein the oxide semiconductor includes at least one of indium, zinc and tin.

3. The thin film transistor substrate as recited in claim 1, wherein the material of the light-blocking layer includes chromium, acrylic resin, or TiO₂.

4. The thin film transistor substrate as recited in claim 1, wherein the thickness of the light-blocking layer is between 0.15 μm and 1.2 μm.

5. The thin film transistor substrate as recited in claim 1, wherein the optical density of the light-blocking layer is between 4 and 6.

6. The thin film transistor substrate as recited in claim 1, wherein the light-blocking layer along a projection direction exceeds the edge of the semiconductor layer by an amount between 1 μm and 2 μm.

7. The thin film transistor substrate as recited in claim 1, further comprising:
a first passivation layer disposed on the light-blocking layer;
a light-absorbing layer disposed on the first passivation layer;
a second passivation layer disposed on the light-absorbing layer; and
a transparent conductive layer disposed on the second passivation layer.

8. The thin film transistor substrate as recited in claim 1, further comprising:
a first passivation layer disposed on the source and the drain;
a light-absorbing layer disposed on the light-blocking layer;
a second passivation layer disposed on the light-absorbing layer; and
a transparent conductive layer disposed on the second passivation layer.

9. The thin film transistor substrate as recited in claim 1, further comprising:
a first passivation layer disposed on the source and the drain;
a light-absorbing layer disposed on the first passivation layer;
a second passivation layer disposed on the light-blocking layer; and
a transparent conductive layer disposed on the second passivation layer.

10. A display device, comprising:
a thin film transistor substrate including a substrate, a gate, a gate insulating layer, a semiconductor layer, a source, a drain and a light-blocking layer, wherein the gate is disposed on the substrate, the gate insulating layer is disposed on the gate, the semiconductor layer is disposed on the gate insulating layer, the source and the drain are disposed on the semiconductor layer with an interval therebetween, the light-blocking layer is disposed on the interval, and the semiconductor layer includes an oxide semiconductor;
an opposite substrate disposed opposite to the thin film transistor substrate; and
an optical element layer disposed between the thin film transistor substrate and the opposite substrate.

11. The display device as recited in claim 10, wherein a backlight module is on the side adjacent to the thin film transistor substrate.

12. The display device as recited in claim 10, wherein the oxide semiconductor includes an oxide, and the oxide includes at least one of indium, zinc and tin.

13. The display device as recited in claim 10, wherein the material of the light-blocking layer includes chromium, acrylic resin, or TiO₂.

14. The display device as recited in claim 10, wherein the thickness of the light-blocking layer is between 0.15 μm and 1.2 μm, and the optical density of the light-blocking layer is between 4 and 6.

15. The display device as recited in claim 10, wherein the light-blocking layer along a projection direction exceeds the edge of the semiconductor layer by an amount between 1 μm and 2 μm.

16. The display device as recited in claim 10, wherein the thin film transistor substrate further comprising:
a first passivation layer disposed on the light-blocking layer;
a light-absorbing layer disposed on the first passivation layer;
a second passivation layer disposed on the light-absorbing layer; and
a transparent conductive layer disposed on the second passivation layer.

17. The display device as recited in claim 10, wherein the thin film transistor substrate further comprising:
a first passivation layer disposed on the source and the drain;
a light-absorbing layer disposed on the light-blocking layer;
a second passivation layer disposed on the light-absorbing layer; and
a transparent conductive layer disposed on the second passivation layer.

18. The display device as recited in claim 10, wherein the thin film transistor substrate further comprising:
a first passivation layer disposed on the source and the drain;
a light-absorbing layer disposed on the first passivation layer;
a second passivation layer disposed on the light-blocking layer; and
a transparent conductive layer disposed on the second passivation layer.

19. The display device as recited in claim 10, wherein a side of the opposite substrate has an electrode layer and a photo-alignment film, and the photo-alignment film is disposed to the electrode layer.
